(19) United States
(12) Patent Application Publication
(10) Pub. No.: US 2024/0053669 A1
(43) Pub. Date: Feb. 15, 2024

(54) EUV PHOTO MASKS AND MANUFACTURING METHOD THEREOF

(71) Applicant: TAIWAN SEMICONDUCTOR MANUFACTURING COMPANY, LTD., Hsinchu (TW)

(72) Inventors: Wen-Chang HSUEH, Longtan Township (TW); Ta-Cheng LIEN, Cyonglin Township (TW); Hsin-Chang LEE, Zhubei City (TW)

(21) Appl. No.: 18/123,749

(22) Filed: Mar. 20, 2023

Related U.S. Application Data
(60) Provisional application No. 63/396,856, filed on Aug. 10, 2022.

(51) Int. Cl. G03F 1/24

(52) U.S. Cl. CPC G03F 1/24

(57) ABSTRACT

A reflective mask includes a substrate, a reflective multilayer disposed on the substrate, a capping layer disposed on the reflective multilayer, a first absorber layer disposed on the capping layer, a first multilayer disposed over the first absorber layer, a second absorber layer disposed on the first multilayer layer, and a second multilayer, which is an uppermost layer of the reflective mask, disposed over the second absorber layer.

### CROSS REFERENCE TO RELATED APPLICATIONS

This application claims the benefit of U.S. Provisional Application No. 63/396,856 filed Aug. 10, 2022, the entirety of which is incorporated by reference herein.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometric size (i.e., the smallest component that can be created using a fabrication process) has decreased.

In one example associated with lithography patterning, a photo mask (or mask) for use in a lithography process is defined with the circuit pattern that will be transferred to the wafers. In advanced lithography technologies, an extreme ultraviolet (EUV) lithography process is used along with a reflective mask. One of the issues to be resolved in an EUV lithography process is a neighboring effect, in which corner portions of exposure areas are exposed multiple times.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1, 2, 3, 4, 5A, 5B, 5C, 5D, 6A and 6B show cross-sectional views of various stages of a process for manufacturing a photo mask, in accordance with some embodiments.

FIGS. 7, 8, 9, 10, and 11A show cross-sectional views and FIG. 11B shows a plan view of various stages of a process for manufacturing a photo mask, in accordance with some embodiments.

FIGS. 12, 13, 14, 15, 16A, 16B, 16C and 17 show cross-sectional views of various stages of a process for manufacturing a photo mask, in accordance with some embodiments.

FIGS. 18, 19, 20 and 21 show cross-sectional views of various stages of a process for manufacturing a photo mask, in accordance with some embodiments.

FIGS. 22A and 22B show cross-sectional views of photo masks, in accordance with some embodiments.

FIG. 23A shows a flowchart of a method making a semiconductor device, and FIGS. 23B, 23C, 23D and 23E show a sequential manufacturing operation of a method of making a semiconductor device in accordance with embodiments of present disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows includes embodiments in which the first and second features are formed in direct contact, and may also include embodiments in which additional features may be formed between the first and second features, such that the first and second features may not be in direct contact. The present disclosure may repeat reference numerals and/or letters in some various examples. This repetition is for the purpose of simplicity and clarity and does not in itself dictate a relationship between some various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

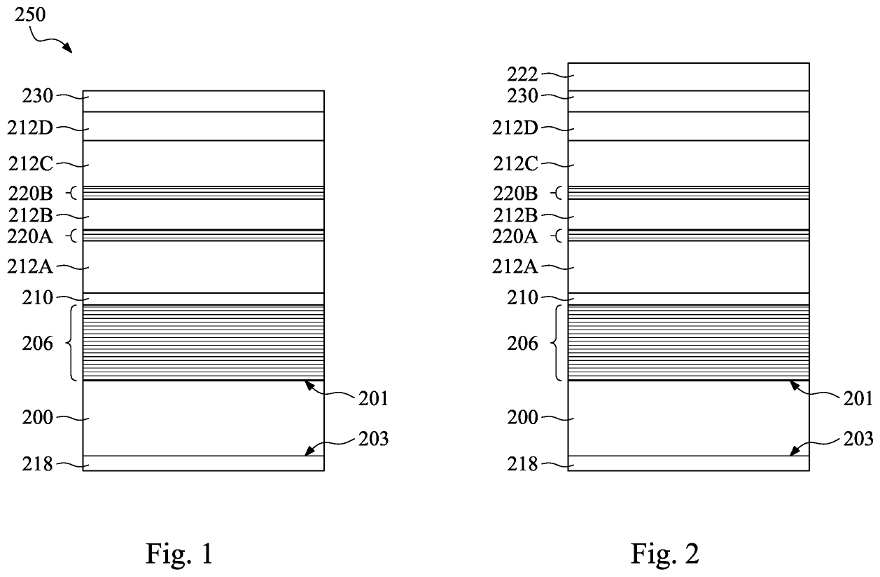

FIGS. 1-6B are cross-sectional views of various stages of a process for manufacturing a photo mask (reticle), in accordance with some embodiments. It is understood that additional operations can be provided before, during, and after processes shown by FIGS. 1-6B, and some of the operations described below can be replaced or eliminated, for additional embodiments of the method. The order of the operations/processes may be interchangeable.

In some embodiments, the photo mask is an extreme ultraviolet (EUV) photo mask. The EUV lithography process utilizes a reflective photo mask rather than a transmissive photo mask. The EUV lithography process utilizes EUV scanners that emit light in the extreme ultraviolet (EUV) region, which is light having an extreme ultraviolet wavelength, such as 10-15 nm. In some embodiments, the EUV source generates EUV with wavelength at about 13.6 nm. Some EUV scanners may use reflective optics, i.e. mirrors and work in the vacuum environment. EUV scanners may provide the desired pattern on an absorption layer (e.g. an “EUV” photo mask absorber) formed on a reflective photo mask. Within the EUV range, all the mask materials are highly absorbing. Thus, reflective optics rather than refractive optics are used.

In some embodiments, the process for manufacturing a photo mask includes a blank photo mask fabrication process and a photo mask patterning process. During the blank photo mask fabrication process, a blank photo mask is formed by depositing suitable layers (e.g. a reflective multilayer, a capping layer and an absorption layer) on a suitable substrate. The blank photo mask is patterned during the photo mask patterning process to have a design of a layer of an integrated circuit (IC). The patterned photo mask is then used to transfer circuit patterns (e.g. the design of a layer of an IC) onto a semiconductor wafer. The patterns on the photo mask can be transferred over and over onto multiple wafers through various lithography processes. Several photo masks (for example, a set of 15 to 30 photo masks) may be used to construct a complete IC. In general, various photo masks are fabricated for use in various lithography processes. Types of EUV photo masks may include the binary intensity mask (BIM) type and the phase-shifting mask (PSM) type.

As shown in FIG. 1, a mask substrate, such as a blank photo mask 250 is received. The blank photo mask 250 includes a mask substate 200 having a front-side surface 201 and a back-side surface 203 opposite to the front-side surface 201. The mask substrate 200 is made of a suitable material, such as a low thermal expansion material (LTEM) or fused quartz in some embodiments. In some embodiments, the LTEM includes TiO₂ doped SiO₂, or another suitable material with low thermal expansion. The mask substrate 200 may serve to minimize image distortion due to mask heating. In addition, the mask substrate 200 may include materials with a low defect level and a smooth surface.

As shown in FIG. 1, a conductive layer 218 is formed over the back-side surface 203 of the mask substrate 200 opposite to the front-side surface 201 of the mask substrate 200. The conductive layer 218 is disposed on the back-side surface 203 of the mask substrate 200 for the electrostatic chucking purpose. In some embodiments, the conductive layer 218 includes tantalum boron (TaB) or chromium nitride (CrN), though other suitable compositions are possible.

As shown in FIG. 1, the first reflective multilayer (ML) 206 is formed over the front-side surface 201 of the mask substrate 200 by a deposition process. In accordance with the Fresnel equations, light reflection occurs when light propagates across an interface between two materials of different refractive indices. The greater the difference between the refractive indices of layers, the higher the intensity of the reflected light becomes as it propagates across the layers. To increase the intensity of the reflected light, in some embodiments, a multilayer of alternating materials may be used to increase the number of interfaces so as to cause the light reflected from each of the different interfaces to interfere constructively. In some embodiments, the first reflective ML 206 includes a plurality of film pairs (e.g. a first layer above or below a second layer in each film pair), such as molybdenum-silicon (Mo/Si) film pairs. In some other embodiments, the first reflective ML 206 may include molybdenum-beryllium (Mo/Be) film pairs, or other suitable materials that are configurable to reflect the EUV light. The characteristics of the first reflective ML 206 are selected such that it provides a high reflectivity to a selected electromagnetic radiation type/wavelength. For example, for the purpose of EUV lithography, the first reflective ML 206 may be designed to reflect light within the EUV range. The thickness of each layer of the first reflective ML 206 depends on the EUV wavelength and the incident angle. Particularly, the thickness of the first reflective ML 206 (and the thicknesses of the film pairs) is adjusted to achieve the maximum constructive interference of the EUV light diffracted at each interface and a minimum absorption of the EUV light. In some embodiments, the number of the film pairs in the first reflective ML 206 is in a range from about twenty to about eighty. However, any number of film pairs may be used. For example, the first reflective ML 206 may include forty pairs of layers of Mo/Si. For example, each Mo/Si film pair has a thickness of about 7 nm and the first reflective ML 206 has a total thickness of 280 nm. In some embodiments, the first layer (e.g., a Si layer) in each Mo/Si film pair has a thickness of about 4 nm. In addition, the second layer (e.g., a Mo layer) in each Mo/Si film pair has a thickness of about 3 nm in some embodiments. In this case, a reflectivity of about 70% is achieved.

In some embodiments, the first reflective ML 206 can be formed by various deposition processes. Examples of the deposition processes include a physical vapor deposition (PVD) process, such as evaporation and DC magnetron sputtering; a plating process such as electrode-less plating or electroplating; a chemical vapor deposition (CVD) process such as atmospheric pressure CVD (APCVD), low pressure CVD (LPCVD), plasma enhanced CVD (PECVD), or high density plasma CVD (HDP CVD); ion beam deposition; spin-on coating; metal-organic decomposition (MOD); and other methods known in the art. MOD is a deposition technique using a liquid-based method in a non-vacuum environment. By using MOD, a metal-organic precursor, dissolved in a solvent, is spin-coated onto a substrate and the solvent is evaporated. A vacuum ultraviolet (VUV) source is used to convert the metal-organic precursors to their constituent metal elements.

Afterwards, a capping layer 210 is formed over the first reflective ML 206. The capping layer 210 is configured to be transparent to EUV light and to protect the first reflective ML 206 from damage and/or oxidation. In addition, the capping layer 210 can serve as an etch stop layer in a patterning or repairing/cleaning process of the absorption layers over the capping layer 210. The capping layer 210 has different etching characteristics from the absorption layers in some embodiments.

In some embodiments, the capping layer 210 is formed of ruthenium (Ru), Ru compounds such as RuB, RuSi, RuN or RuON, chromium (Cr), Cr oxide, and Cr nitride. boron (B), boron nitride and boron carbide. For example, the processes of the mask substrate 200, the capping layer 210 may be similar to, or the same as, those of the first reflective ML 206, and the details thereof are not repeated herein. For example, a low-temperature deposition process is often chosen for the capping layer 210 to prevent inter-diffusion of the first reflective ML 206. In some embodiments, the thickness of the capping layer 210 is in a range from about 2 nm to about 5 nm.

Afterwards, a first absorption layer 212A is deposited over the capping layer 210. In some embodiments, the first absorption layer 212A is an absorption material to absorb radiation in the EUV wavelength range projected onto the pattern portion of the photo mask. For example, the photo mask 250A can be referred to as a Binary Intensity Photo mask (BIM). In some embodiments, the first absorption layer 212A is a part of patterns according to an IC layout pattern (or simply IC pattern).

In some embodiments, the first absorption layer 212A is formed of Ta-based materials. In some embodiments, the first absorption layer 212A is formed of tantalum boron nitride (TaBN), TaBO or TaN. In some embodiments, the first absorption layer 212A includes Ta and one or more elements of Mo, Si, Cr, Pt, Re, Co, Te, Ni, W, Al, Nb, Zr, V, Y, Rh, Ir, Pd or Ru. In some embodiments, the first absorption layer 212A includes one or more layers of chromium, chromium oxide, chromium nitride, titanium, titanium oxide, titanium nitride, tantalum, tantalum oxide, tantalum nitride, tantalum oxynitride, tantalum boron oxide, tantalum boron oxynitride, aluminum, aluminum-copper, aluminum oxide, silver, silver oxide, palladium, ruthenium, molybdenum, other suitable materials, and/or mixture of some of the above. In some embodiments, the thickness of the first absorption layer 212A is in a range from about 1 nm to about 70 nm.

Next, a first adjust layer 220A is formed over the first absorption layer 212A. In some embodiments, the first adjust layer 220A includes a multilayer (ML) of Mo/Si film pairs. In some embodiments, the first adjust layer 220A includes two, three, four or five pairs of a Mo layer and a Si layer. In some embodiments, the thickness of the Si layer is greater than the thickness of the Mo layer in each pair. In some embodiments, the thickness of the Mo layer is in a range from about 1.5 nm to about 4.5 nm. In some embodiments, the thickness of the Si layer is in a range from about 2 nm to about 6 nm. In some embodiments, the thickness of the Mo layer and Si layer is about 1.5 nm and about 2 nm, about 3 nm and about 4 nm, or about 4.5 nm and about 6 nm, respectively. The total thickness of the first adjust layer 220A is in a range from about 7 nm to about 52.5 nm in some embodiments. The first adjust layer 220A has an EUV reflectivity less than about 0.1% in some embodiments. The first adjust layer 220A is substantially EUV transmissive in some embodiments.

Further, a second absorption layer 212B is formed over the first adjust layer 220A. In some embodiments, the materials, configurations, structures and/or processes of the second absorption layer 212B are similar to, or the same as, those of the first absorption layer 212A. In some embodiments, the second absorption layer 212B is made of a different material than the first absorption layer 212A. In some embodiments, the second absorption layer 212B includes one or more of Pt, Re, Co, Te, Ni, W, Al, Nb, Zr, V, Y, Rh, Jr, Ti, Pd or Ru or alloys thereof. In some embodiments, the second absorption layer 212B includes TaBO, platinum or a platinum alloy, Jr or an Jr alloy, or Cr or a Cr alloy. In some embodiments, the thickness of the second absorption layer 212B is in a range from about 1 nm to about 30 nm.

Next, a second adjust layer 220B is formed over the second absorption layer 212B. In some embodiments, the second adjust layer 220B includes a multilayer (ML) of Mo/Si film pairs. In some embodiments, the second adjust layer 220B includes two, three, four or five pairs of a Mo layer and a Si layer. In some embodiments, the thickness of the Si layer is greater than the thickness of the Mo layer in each pair. In some embodiments, the thickness of the Mo layer is in a range from about 1.5 nm to about 4.5 nm. In some embodiments, the thickness of the Si layer is in a range from about 2 nm to about 6 nm. In some embodiments, the thickness of the Mo layer and Si layer is about 1.5 nm and about 2 nm, about 3 nm and about 4 nm, or about 4.5 nm and about 6 nm, respectively. The second adjust layer 220B has an EUV reflectivity less than about 0.1% in some embodiments. The second adjust layer 220B is substantially EUV transmissive in some embodiments. The total thickness of the second adjust layer 220B is in a range from about 7 nm to about 52.5 nm in some embodiments. In some embodiments, the materials, configurations, structures (e.g., number of pairs, thickness), and/or processes of the second adjust layer 220B are similar to, or the same as, those of the first adjust layer 220A, and in other embodiments, at least one of the materials, configurations, structures and/or processes of the second adjust layer 220B is different from that of the first adjust layer 220A.

Further, a third absorption layer 212C is formed over the second adjust layer 220B. In some embodiments, the materials, configurations, structures and/or processes of the third absorption layer 212B are similar to, or the same as, those of the first and/or second absorption layers as set forth above. In some embodiments, the third absorption layer 212C is made of a different material than the first and/or second absorption layers. In some embodiments, the third absorption layer 212C includes TaBN, TaON, TaBO or tantalum oxide (TaO). In some embodiments, the third absorption layer 212C includes CrN, CrON or chromium oxide. In some embodiments, the first absorption layer 212A includes Ta or Cr and one or more elements of Mo, Si, Pt, Re, Co, Te, Ni, W, Al, Nb, Zr, V, Y, Rh, Jr, or Ru. In some embodiments, the thickness of the third absorption layer 212C is in a range from about 1 nm to about 70 nm.

Moreover, a fourth absorption layer 212D is formed over the third absorption layer 212C. In some embodiments, the materials, configurations, structures and/or processes of the fourth absorption layer 212C are similar to, or the same as, those of the first, second and/or third absorption layers as set forth above. In some embodiments, the fourth absorption layer 212D is made of a different material than the first, second and/or third absorption layers. In some embodiments, the fourth absorption layer 212D includes a silicide or a Si compound. In some embodiments, the fourth absorption layer 212D includes tantalum silicide, or titanium silicide. In some embodiments, the first absorption layer 212A includes Ta, Si or Cr and one or more elements of Mo, Pt, Re, Co, Te, Ni, W, Al, Nb, Zr, V, Y, Rh, Jr, Pd, or Ru. In some embodiments, the thickness of the fourth absorption layer 212C is in a range from about 1 nm to about 30 nm.

Further, a hard mask layer 230 is formed over the fourth absorption layer 212D, as shown in FIG. 1. In some embodiments, the hard mask layer 230 is formed of silicon oxide, silicon nitride, silicon oxynitride, silicon carbide, metal oxide, metal nitride or metal oxynitride, another suitable material, or a combination thereof. In some embodiments, the hard mask layer 230 is formed of tantalum boron nitride (TaBN), chromium oxynitride, aluminum oxynitride, or a combination thereof. The hard mask layer 230 can be formed by a deposition process including a chemical vapor deposition (CVD) process, a physical vapor deposition (PVD) process, an atomic layer deposition (ALD) process and/or another suitable process.

Afterwards, a photoresist layer 222 is formed over the hard mask layer 230 of the blank photo mask, as shown in FIG. 2 in accordance with some embodiments. The photoresist layer 222 may include a positive photoresist layer and may be formed by a spin-on coating process followed by a soft baking process.

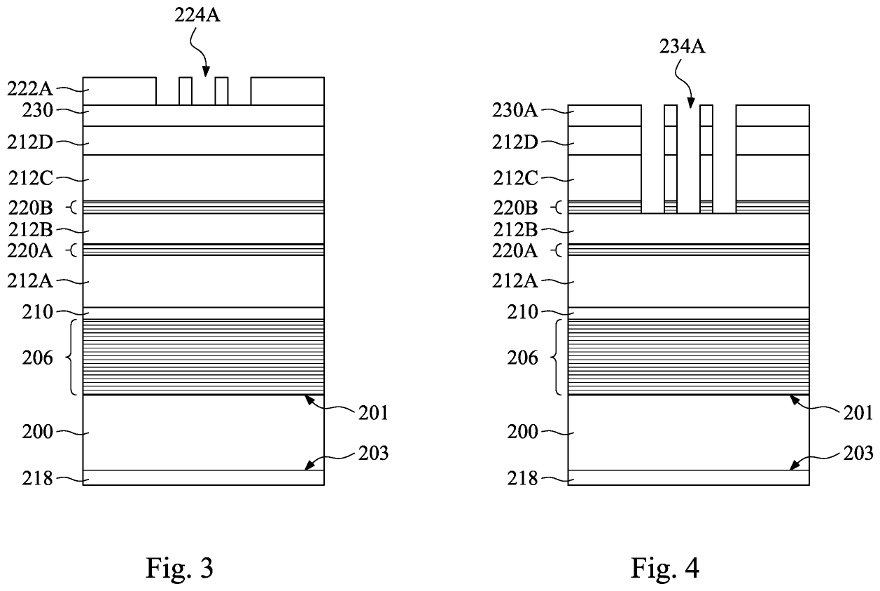

Then, the photoresist layer 222 is patterned to form photoresist patterns 222A on the hard mask layer 220 by a patterning process, as shown in FIG. 3 in accordance with some embodiments. In some embodiments, the patterning process includes a photolithography process. The photolithography process is configured to form openings 224A in the photoresist layer 222 as shown in FIG. 3. The openings 224A are formed passing through the photoresist layer 222 to expose the hard mask layer 230. In some embodiments, the photolithography process includes exposure, post-exposure baking, developing, rinsing, drying (e.g. hard baking), other suitable processes, and/or combinations thereof to form the photoresist patterns 222A. For example, electron, ion, or photon beam direct writing may be used for the exposure step in the mask patterning process.

Afterwards, a portion of the hard mask layer 230 that is not covered by the photoresist patterns 222A is removed by an etching process to form a hard mask pattern 230A. In some embodiments, the etching process substantially stops on the fourth absorption layer 212D to form openings in the hard mask layer 230. The openings are formed passing through the hard mask layer 230 to expose the fourth absorption layer 212D. In some embodiments, the etching process includes a dry etching process performed using a halogen-based gas mixed with O₂, N₂, and H₂O and a carrier gas such as He or Ar or mixtures thereof, to remove the uncovered portion of the hard mask layer 230. The halogen-based gas may include C₁₂, CHF₃, CH₃F, C₄F₈, CF₄, SF₆, CF₃Cl, or a mixture thereof. In some embodiments, the etching process includes using Cl₂ and O₂. In some embodiments, the etching process includes using CF₃Cl and O₂.

After performing the etching processes of the hard mask layer 230, the photoresist pattern 222A is removed in some embodiments. For example, the photoresist pattern 222A may be removed by a wet etching process or other applicable processes after performing the etching processes of the hard mask layer 230. The wet etching process, for example, a photoresist stripping process, may use a photoresist stripper, an aqueous alkaline solution, an amine-solvent mixture, or an organic solvent.

Afterwards, a first patterning process is performed to remove portions of the fourth absorption layer 212D, the third absorption layer 212C and the second adjust layer 220B until the second absorption layer 212B is exposed, to form the openings 234A, as shown in FIG. 4 in accordance with some embodiments. Thus, the material of the second absorption layer 212B is selected such that the second absorption layer 212B functions as an etch stop layer.

In some embodiments, the first patterning process includes multiple etching steps using different conditions (e.g., gases) according to the material to be etched. In some embodiments, the second adjust layer 220B functions as an etch stop layer when etching the fourth and third absorption layers.

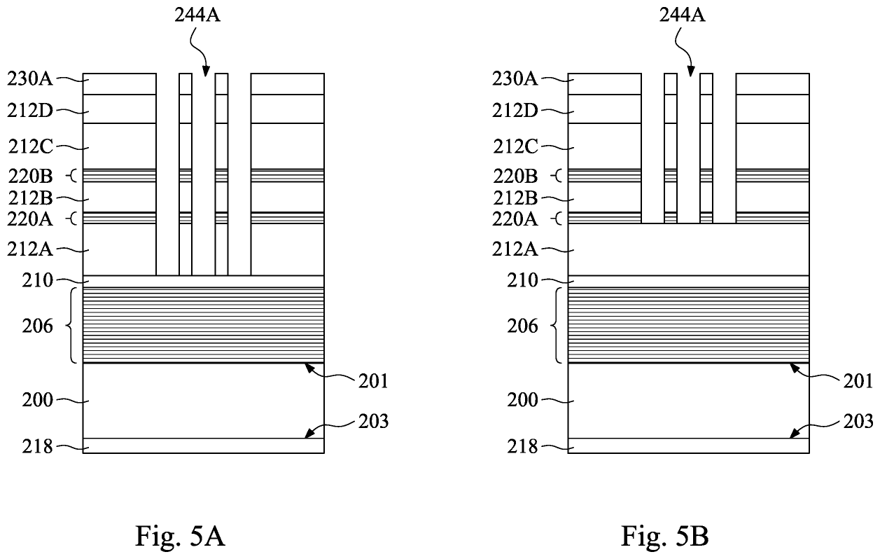

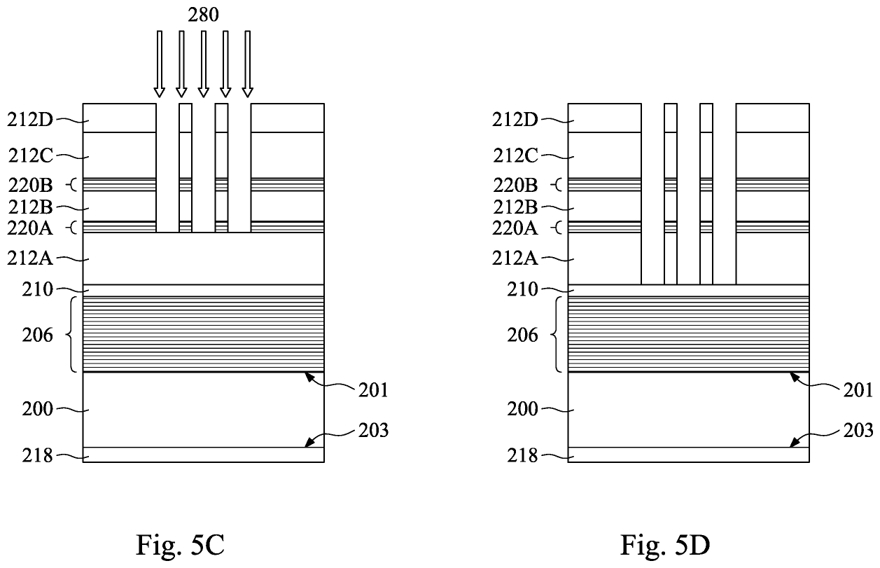

Further, a second patterning process is performed to form openings 244A passing through the second adjust layer 220B, the second absorption layer 212B, the first adjust layer 220A and the first absorption layer 212A until the capping layer 210 is exposed, as shown in FIG. 5A in accordance with some embodiments. In some embodiments, one or more etching conditions (e.g., gas) are changed during the second patterning process in accordance with the material to be etched. In some embodiments, the second patterning process includes multiple etching steps using different conditions (e.g., gases) according to the material to be etched. In some embodiments, the first adjust layer 220A functions as an etch stop layer when etching the second absorption layer 212B.

In some embodiments, as shown in FIG. 5B, the etching operation stops when the first absorption layer 212A is exposed. In some embodiments, after the hard mask layer 230A is removed, a surface treatment 280 is performed to protect side faces of the second absorption layer 212B as shown in FIG. 5C. In some embodiments, a thin silicon containing layer is formed on the side faces of the second absorption layer 212B. In some embodiments, the surface treatment 280 includes applying hexamethyldisilazane (HMDS). Molecules of Si(CH₃) are coupled to the surface metal atom of the second absorption layer 212B via an oxygen atom to form a silicon containing layer. In some embodiments, the surface treatment 280 is performed before the hard mask pattern 230A is removed.

After the surface treatment, the first absorption layer 212A is etched as shown in FIG. 5D. By adjusting one or more conditions in the surface treatment, the side-etching of the second absorption layer 212B is controlled to obtain substantially same pattern width between the first absorption layer 212A and the second absorption layer 212B. In some embodiments, the difference in width is greater than 0% to less than about 5% of the width of the first absorption layer 212A.

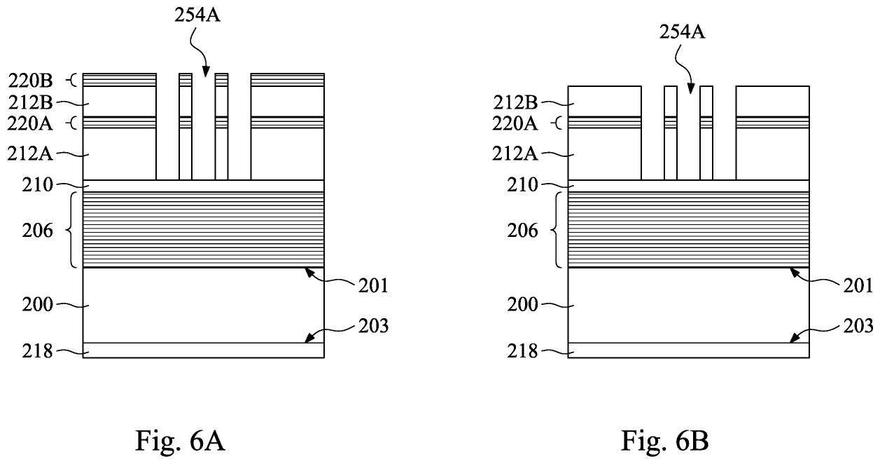

Then, as shown in FIG. 6A, the hard mask pattern 230A, the patterned fourth absorption layer 212D and the patterned third absorption layer 212C are removed, as shown in FIG. 6A. In some embodiments, one or more dry and/or wet etching operations are performed to remove these layers, and in other embodiments, a chemical mechanical polishing (CMP) operation is performed to remove these layers. After the removal operation, the patterned second adjust layer 220B, the patterned second absorption layer 212B, the patterned first adjust layer 220A and the patterned first absorption layer 212A collectively form a patterned absorption structure as opaque patterns of the reflective photomask, while the trenches between the absorption structures are bright, reflective patterns.

In some embodiments, as shown in FIG. 6B, the second adjust layer 220B is also removed so that the patterned second absorption layer 212B, the patterned first adjust layer 220A and the patterned first absorption layer 212A collectively form a patterned absorption structure as opaque patterns of the reflective photomask, while the trenches between the absorption structures are bright, reflective patterns.

In some embodiments, one of the third or the fourth absorption layers 212C, 212D is omitted, or the third and the fourth absorption layers are made of the same material as one layer.

In some embodiments, the sidewall profile of the patterns of at least one of the first absorption layer 212A or the second absorption layer 212B can be improved by adjusting one or more of the thickness and reflectivity of the first and/or second adjust layers.

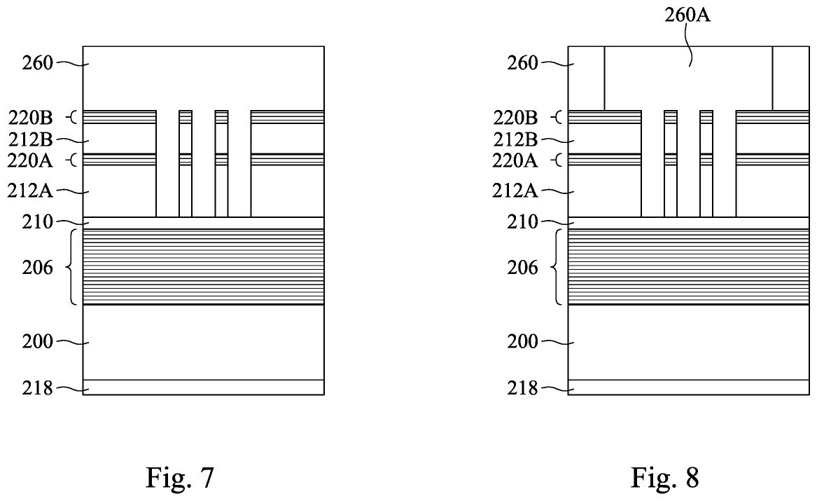

FIGS. 7-11A show cross sectional views of various stages of a sequential photo mask manufacturing operation according to an embodiment of the present disclosure. It is understood that additional operations can be provided before, during, and after processes shown by FIGS. 7-11A, and some of the operations described below can be replaced or eliminated, for additional embodiments of the method. The order of the operations/processes may be interchangeable. Materials, configurations, processes and/or dimensions as explained with respect to the foregoing embodiments may be employed in the following embodiments and detailed description thereof may be omitted.

In some embodiments, after the structure of FIG. 6A is formed, a photo resist layer 260 is formed in the trenches and over the second adjust layer 220B, as shown in FIG. 7.

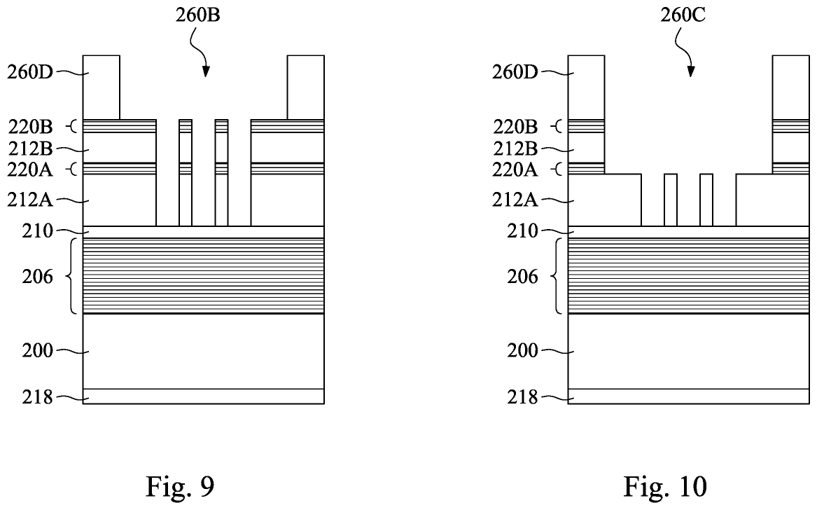

Then, the photoresist layer 260 is patterned to form a latent photoresist pattern 260A as shown in FIG. 8, and a developed photoresist pattern 260B as shown in FIG. 9. In some embodiments, the patterning process includes a photolithography process. In some embodiments, the photolithography process includes exposure, post-exposure baking, developing, rinsing, drying (e.g. hard baking), other suitable processes, and/or combinations thereof to form the photoresist pattern. For example, electron, ion, or photon beam direct writing may be used for the exposure step in the mask patterning process.

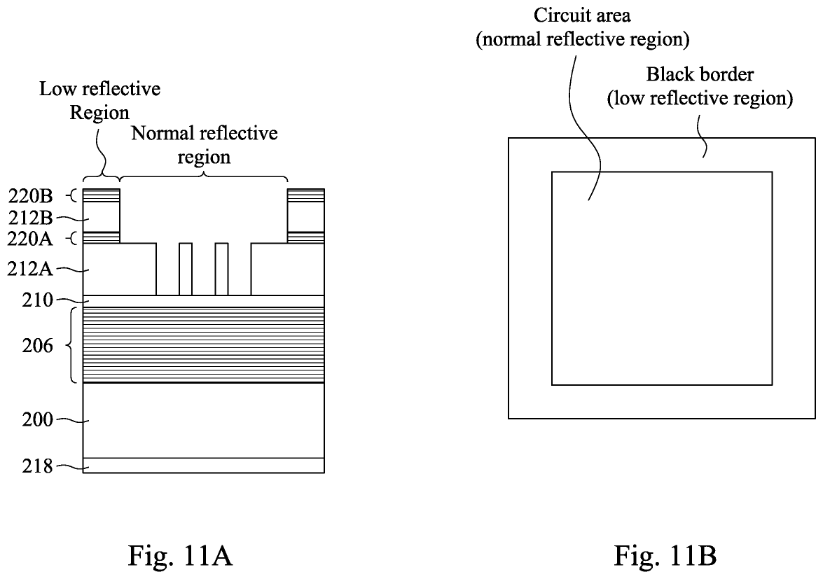

Subsequently, the second adjust layer 220B, the second absorption layer 212B and the first adjust layer 220A are removed by one or more etching operations using the photo resist pattern 260D as an etching mask, as shown in FIG. 10. Then, the photo resist layer is removed as shown in FIG. 11A.

The photo mask shown in FIGS. 11A and 11B (a plan or layout view) includes a low reflective region and a normal reflective region. In some embodiments, the low reflective region includes a black border pattern. In the present application, the black border pattern has a lower reflectivity, and thus it is possible to reduce neighboring effects in an EUV lithography operation. The normal reflective region is used as a circuit area. The black border region further includes a trench opening surrounding the circuit area, in which all the layers from the ML 206 to the second adjust layer 220B are removed.

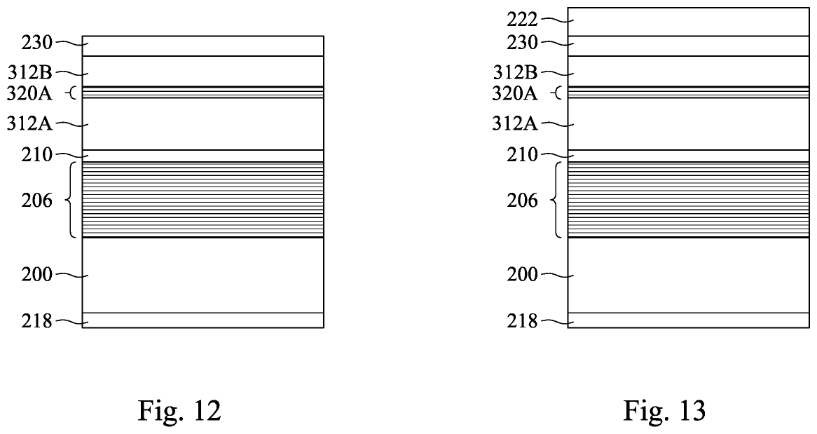

FIGS. 12-17 show cross sectional views of various stages of a sequential photo mask manufacturing operation according to an embodiment of the present disclosure. It is understood that additional operations can be provided before, during, and after processes shown by FIGS. 12-17, and some of the operations described below can be replaced or eliminated, for additional embodiments of the method. The order of the operations/processes may be interchangeable. Materials, configurations, processes and/or dimensions as explained with respect to the foregoing embodiments may be employed in the following embodiments and detailed description thereof may be omitted.

In some embodiments, as shown in FIG. 12, a blank mask structure includes a substrate 200, a first reflective multilayer (ML) 206 disposed over the substrate 200, a capping layer 210 disposed over the first ML 206, a lower absorption layer 312A disposed over the capping layer 210, an adjust layer 320A disposed over the lower absorption layer 312A, and an upper absorption layer 312B disposed over the adjust layer 320A. In some embodiments, a hard mask layer 230 is disposed over the upper absorption layer 312B.

In some embodiments, each of the lower absorption layer 312A and the upper absorption layer 312B includes a material the same as one of the materials for the first, second, third or fourth absorption layers as set forth above. In some embodiments, the upper absorption layer 312B is made of the same material as or different material than the lower absorption layer 312A. In some embodiments, the lower absorption layer 312A is made of the same material as the second absorption layer 212B as set forth above. In some embodiments, the upper absorption layer 312B is made of the same material as the fourth absorption layer 212D as set forth above. In other embodiments, the lower absorption layer 312A is made of the same material as the first absorption layer 212A, and the upper absorption layer 312B is made of the same material as the second or third absorption layers 212B or 212C as set forth above.

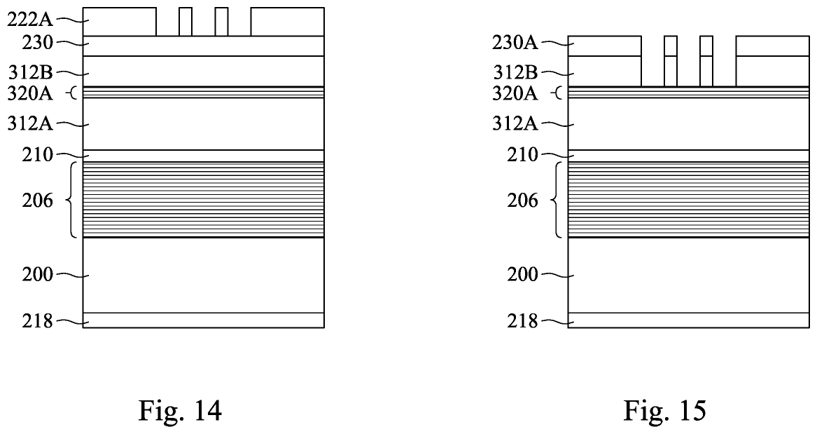

A photoresist layer 222 is formed over the hard mask layer 230 of the blank photo mask, as shown in FIG. 13, similar to the operation as explained with respect to FIG. 2. Then, the photoresist layer 222 is patterned to form photoresist patterns 222A on the hard mask layer 220 by a patterning process, as shown in FIG. 14, similar to the operation as explained with respect to FIG. 3.

Afterwards, a portion of the hard mask layer 230 that is not covered by the photoresist patterns 222A is removed by an etching process to form a hard mask pattern 230A. In some embodiments, the etching process substantially stops on the upper absorption layer 312B to form openings in the hard mask layer 230. The openings are formed passing through the hard mask layer 230 to expose the upper absorption layer 312B. After performing the etching processes of the hard mask layer 230, the photoresist patterns 222A is removed in some embodiments.

Then, a first patterning process is performed to remove portions of the upper absorption layer 312B until the adjust layer 320A is exposed, as shown in FIG. 15.

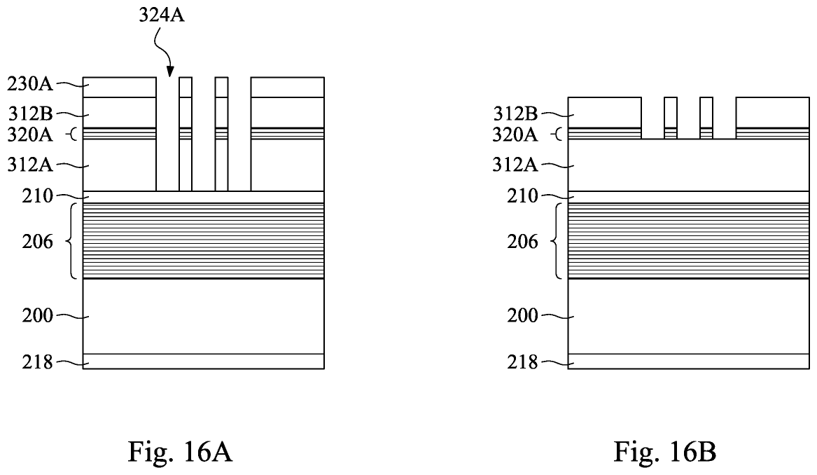

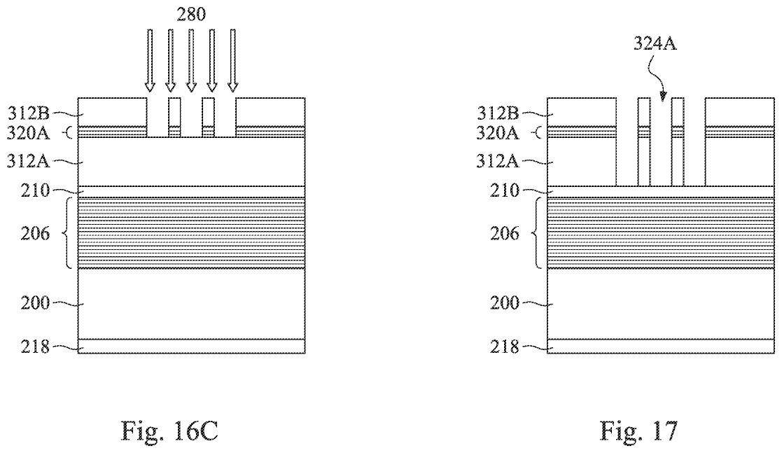

Further, a second patterning process is performed to form openings 324A passing through the upper absorption layer 312B, the adjust layer 320A and the lower absorption layer 312A until the capping layer 210 is exposed, as shown in FIG. 16A. In some embodiments, one or more etching conditions (e.g., gas) are changed during the second patterning process in accordance with the material to be etched. Then, the hard mask layer 230A is removed by one or more etching operations or a CMP operation as shown in FIG. 17.

In some embodiments, as shown in FIG. 16B, the etching operation stops when the first absorption layer 312A is exposed. In some embodiments, after the hard mask layer 230A is removed, a surface treatment 280 is performed to protect side faces of the second absorption layer 312B as shown in FIG. 16C. In some embodiments, a thin silicon containing layer is formed on the side faces of the second absorption layer 312B. In some embodiments, the surface treatment 280 includes applying hexamethyldisilazane (HMDS). Molecules of Si(CH₃) are coupled to the surface metal atom of the second absorption layer 312B via an oxygen atom to form a silicon containing layer. In some embodiments, the surface treatment 280 is performed before the hard mask pattern 230A is removed.

After the surface treatment, the first absorption layer 312A is etched as shown in FIG. 17. By adjusting one or more conditions in the surface treatment, the side-etching of the second absorption layer 312B is controlled to obtain substantially same pattern width between the first absorption layer 312A and the second absorption layer 312B. In some embodiments, the difference in width is greater than 0% to less than about 5% of the width of the first absorption layer 312A.

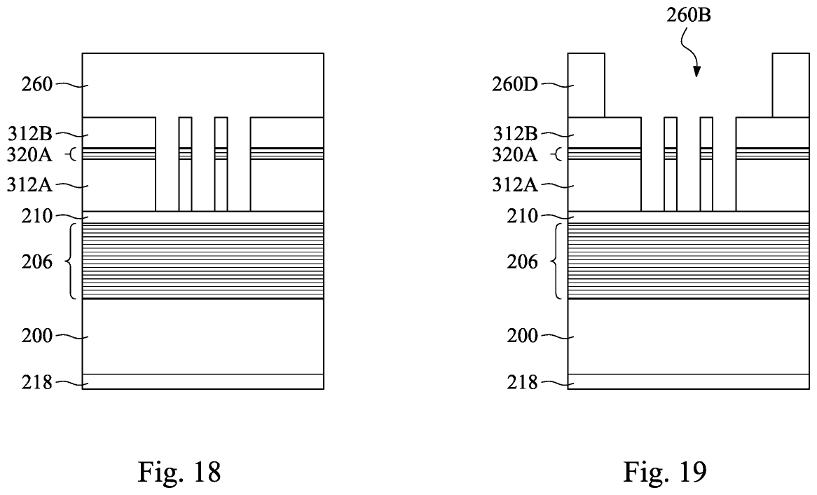

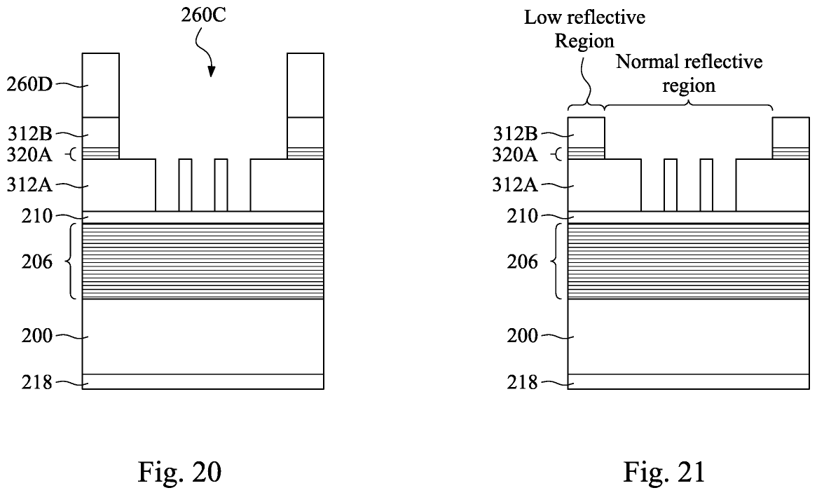

FIGS. 18-21 show cross sectional views of various stages of a sequential photo mask manufacturing operation according to an embodiment of the present disclosure. It is understood that additional operations can be provided before, during, and after processes shown by FIGS. 18-21, and some of the operations described below can be replaced or eliminated, for additional embodiments of the method. The order of the operations/processes may be interchangeable. Materials, configurations, processes and/or dimensions as explained with respect to the foregoing embodiments may be employed in the following embodiments and detailed description thereof may be omitted.

In some embodiments, after the structure of FIG. 6B or 17 is formed, a photo resist layer 260 is formed in the trenches and over the upper absorption layer 312B, as shown in FIG. 18. Then, the photoresist layer 260 is patterned to form a developed photoresist pattern 260B as shown in FIG. 19. Subsequently, the upper absorption layer 312B and the adjust layer 320A are removed by one or more etching operations using the photo resist pattern 260D as an etching mask. Then, the photo resist layer is removed as shown in FIG. 21.

The photo mask shown in FIG. 21 includes a low reflective region and a normal reflective region. In some embodiments, the low reflective region includes a black border pattern. In the present application, the black border pattern has a lower reflectivity, and thus it is possible to reduce neighboring effects in an EUV lithography operation. The normal reflective regions are used as circuit patterns.

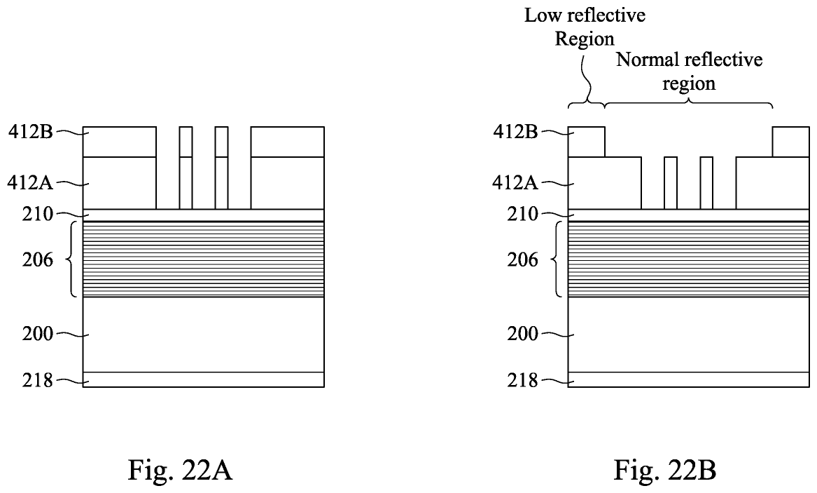

In some embodiments, the EUV photo mask includes two absorption layers 412A and 412B as shown in FIGS. 22A and 22B. In some embodiments, the configuration of the first absorption layer 412A is the same as the configuration of the first absorption layer 212A as set forth above, and the configuration of the second absorption layer 412B is the same as the configuration of the second absorption layer 212B as set forth above. In some embodiments, the first absorption layer 412A is made of TaN, and the second absorption layer 412B is made of Pt (greater than 99% Pt).

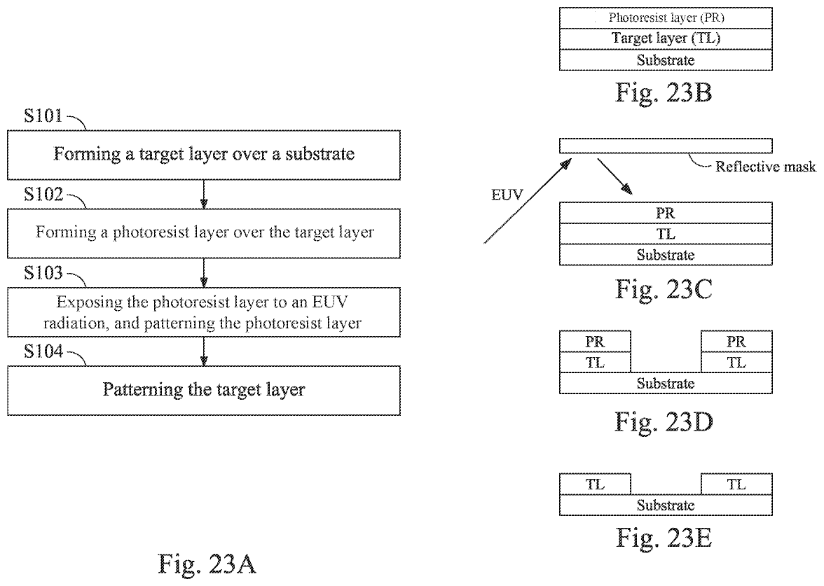

FIG. 23A shows a flowchart of a method making a semiconductor device, and FIGS. 23B, 23C, 23D and 23E show a sequential manufacturing operation of the method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S101 of FIG. 23A, a target layer to be patterned is formed over the semiconductor substrate. In certain embodiments, the target layer is the semiconductor substrate. In some embodiments, the target layer includes a conductive layer, such as a metallic layer or a polysilicon layer, a dielectric layer, such as silicon oxide, silicon nitride, SiON, SiOC, SiOCN, SiCN, hafnium oxide, or aluminum oxide, or a semiconductor layer, such as an epitaxially formed semiconductor layer. In some embodiments, the target layer is formed over an underlying structure, such as isolation structures, transistors or wirings. At S102, of FIG. 23A, a photo resist layer is formed over the target layer, as shown in FIG. 23B. The photo resist layer is sensitive to the radiation from the exposure source during a subsequent photolithography exposing process. In the present embodiment, the photo resist layer is sensitive to EUV light used in the photolithography exposing process. The photo resist layer may be formed over the target layer by spin-on coating or other suitable technique. The coated photo resist layer may be further baked to drive out solvent in the photo resist layer. At S103 of FIG. 23A, the photoresist layer is patterned using an EUV reflective mask as set forth above, as shown in FIG. 23B. The patterning of the photoresist layer includes performing a photolithography exposing process by an EUV exposing system using the EUV mask. During the exposing process, the integrated circuit (IC) design pattern defined on the EUV mask is imaged to the photoresist layer to form a latent pattern thereon. The patterning of the photoresist layer further includes developing the exposed photoresist layer to form a patterned photoresist layer having one or more openings. In one embodiment where the photoresist layer is a positive tone photoresist layer, the exposed portions of the photoresist layer are removed during the developing process. The patterning of the photoresist layer may further include other process steps, such as various baking steps at different stages. For example, a post-exposure-baking (PEB) process may be implemented after the photolithography exposing process and before the developing process.

At S104 of FIG. 23A, the target layer is patterned utilizing the patterned photoresist layer as an etching mask, as shown in FIG. 23D. In some embodiments, the patterning the target layer includes applying an etching process to the target layer using the patterned photoresist layer as an etch mask. The portions of the target layer exposed within the openings of the patterned photoresist layer are etched while the remaining portions are protected from etching. Further, the patterned photoresist layer may be removed by wet stripping or plasma ashing, as shown in FIG. 23E.

In the foregoing embodiments, the materials of the capping layer, the hard mask layer and/or the first to fourth absorption layers can be selected from Ta, B, O, N, Mo, Si, Cr, Pt, Re, Co, Te, Ni, W, Al, Nb, Zr, V, Y, Rh, Ir, Ti or Ru, or an alloy thereof, in view of etching selectivity, absorption coefficient, and/or reflectivity. Any material combinations of the layers are within the scope of the present disclosure.

As described above, the EUV reflective photo mask includes multiple absorption layers with one or more adjust layers, which includes a small number of Mo/Si pair layers. The absorption layers can be patterned by a two-step patterning process (e.g., the first patterning processes and the second patterning processes). In addition, the two-step patterning process can be more precisely controlled by the use of a surface treatment process. The wafer neighboring effect may be reduced or eliminated in some embodiments.

It will be understood that not all advantages have been necessarily discussed herein, no particular advantage is required for all embodiments or examples, and other embodiments or examples may offer different advantages.

According to one aspect of the present application, in a method of manufacturing a reflective mask, a photo resist layer is formed over a mask blank. The mask blank includes a substrate, a reflective multilayer on the substrate, a capping layer on the reflective multilayer, a first absorption layer on the capping layer, a first adjust layer on the first absorption layer, a second absorption layer on the first adjust layer, a second adjust layer on the second absorption layer, a third absorption layer on the second adjust layer, a fourth absorption layer on the third absorption layer and a hard mask layer on the fourth absorption layer. The photo resist layer is patterned, the hard mask layer is patterned by using the patterned photo resist layer as an etching mask, a first absorber patterning is performed to pattern the fourth absorption layer, the third absorption layer and the second adjust layer by using the patterned hard mask layer as an etching mask, a second absorber patterning is performed to pattern the first adjust layer, the second absorption layer and the first absorption layer by using the patterned fourth and third absorption layers as an etching mask, and the patterned fourth and third absorption layers are removed. In one or more of the foregoing and following embodiments, at least one of the first and second adjust layers includes one or more pairs of a Si layer and a Mo layer. In one or more of the foregoing and following embodiments, a number of pairs is 2 to 5. In one or more of the foregoing and following embodiments, at least one of a thickness of Si, a thickness of Mo or the number of pairs is different between the first adjust layer and the second adjust layer. In one or more of the foregoing and following embodiments, materials of the first, second, third and fourth absorption layers are different from each other. In one or more of the foregoing and following embodiments, the first absorption layer includes TaN. In one or more of the foregoing and following embodiments, the second absorption layer includes one or more of Pt, Ir, Re, Ru or an alloy thereof. In one or more of the foregoing and following embodiments, the third absorption layer includes at least one of TaO or TaBO. In one or more of the foregoing and following embodiments, the fourth absorption layer include silicide. In one or more of the foregoing and following embodiments, in the second absorber patterning, the second absorption layer and the first adjust layer are patterned, after the first adjust layer is patterned, the patterned hard mask layer is removed, and the first absorption layer is patterned. In one or more of the foregoing and following embodiments, the second absorber patterning further comprises forming a Si containing layer on side faces of patterned second absorption layer before the first absorption layer is patterned. In one or more of the foregoing and following embodiments, absorber patterns composed of the first absorption layer is formed by removing a part of the second adjust layer, the second absorption layer and the first adjust layer. In one or more of the foregoing and following embodiments, a black border region includes the first absorption layer, the first adjust layer, the second absorption layer and the second adjust layer. In one or more of the foregoing and following embodiments, the patterned second adjust layer is removed.

In accordance with another aspect of the present disclosure, in a method of manufacturing a reflective mask, a photo resist layer is formed over a mask blank. The mask blank includes a substrate, a reflective multilayer on the substrate, a capping layer on the reflective multilayer, a first absorption layer on the capping layer, an adjust layer on the first absorption layer, a second absorption layer on the adjust layer and a hard mask layer on the second absorption layer. The photo resist layer is patterned, the hard mask layer is patterned by using the patterned photo resist layer as an etching mask, a first absorber patterning is performed to pattern the second absorption layer by using the patterned hard mask layer as an etching mask, a second absorber patterning is performed to pattern the adjust layer and the first absorption layer by using the patterned second absorption layer as an etching mask, absorber patterns composed of the first absorption layer is formed by removing a part of the second absorption layer and the adjust layer. In one or more of the foregoing and following embodiments, a black border region includes the first absorption layer, the adjust layer and the second absorption layer. In one or more of the foregoing and following embodiments, the adjust layer includes 2 to 5 pairs of a Si layer and a Mo layer. In one or more of the foregoing and following embodiments, a thickness of the Si layer is in a range from 2 nm to 6 nm and a thickness of the Mo layer is smaller than the thickness of the Si layer and is in a range from 1.5 nm to 4.5 nm. In one or more of the foregoing and following embodiments, materials of the first and second absorption layers are different from each other. In one or more of the foregoing and following embodiments, the second absorption layer include silicide, and the first absorption layer includes Pt. In one or more of the foregoing and following embodiments, in the second absorber patterning, the adjust layer is patterned, after the adjust layer is patterned, the patterned hard mask layer is removed, and the first absorption layer is patterned. In one or more of the foregoing and following embodiments, the second absorber patterning further comprises performing a surface treatment on side faces of patterned second absorption layer before the first absorption layer is patterned.

In accordance with another aspect of the present disclosure, in a method of manufacturing a reflective mask, a photo resist layer over a mask blank. The mask blank includes a substrate, a reflective multilayer on the substrate, a capping layer on the reflective multilayer, a first absorption layer on the capping layer, a first adjust layer on the first absorption layer, a second absorption layer on the first adjust layer, a second adjust layer on the second absorption layer, a third absorption layer on the second adjust layer and a hard mask layer on the third absorption layer. The photo resist layer is patterned, the hard mask layer is patterned by using the patterned photo resist layer as an etching mask, a first absorber patterning is performed to pattern the third absorption layer and the second adjust layer by using the patterned hard mask layer as an etching mask, a second absorber patterning is performed to pattern the first adjust layer, the second absorption layer and the first absorption layer by using the patterned fourth and third absorption layers as an etching mask, and the patterned third absorption layer is removed. In one or more of the foregoing and following embodiments, at least one of the first and second adjust layers includes one or more pairs of a Si layer and a Mo layer. In one or more of the foregoing and following embodiments, a number of pairs is 2 to 5. In one or more of the foregoing and following embodiments, at least one of a thickness of Si, a thickness of Mo or the number of pairs is different between the first adjust layer and the second adjust layer. In one or more of the foregoing and following embodiments, materials of the first, second and third layers are different from each other. In one or more of the foregoing and following embodiments, the first absorption layer includes TaN. In one or more of the foregoing and following embodiments, the second absorption layer includes one or more of Pt, Ir, Re, Ru or an alloy thereof. In one or more of the foregoing and following embodiments, the third absorption layer includes at least one of TaO or silicide. In one or more of the foregoing and following embodiments, in the second absorber patterning, the second absorption layer and the first adjust layer are patterned, after the first adjust layer is patterned, the patterned hard mask layer is removed, and the first absorption layer is patterned. In one or more of the foregoing and following embodiments, the second absorber patterning further comprises forming a Si containing layer on side faces of patterned second absorption layer before the first absorption layer is patterned. In one or more of the foregoing and following embodiments, absorber patterns composed of the first absorption layer are formed by removing a part of the second adjust layer, the second absorption layer and the first adjust layer. In one or more of the foregoing and following embodiments, a black border region includes the first absorption layer, the first adjust layer, the second absorption layer and the second adjust layer. In one or more of the foregoing and following embodiments, the patterned second adjust layer is removed.

In accordance with another aspect of the present disclosure, a reflective mask includes a substrate, a reflective multilayer disposed on the substrate, a capping layer disposed on the reflective multilayer, a first absorber layer disposed on the capping layer, a first multilayer disposed over the first absorber layer, a second absorber layer disposed on the first multilayer layer, and a second multilayer, which is an uppermost layer of the reflective mask, disposed over the second absorber layer. In one or more of the foregoing and following embodiments, at least one of the first and second multilayers includes one or more pairs of a Si layer and a Mo layer. In one or more of the foregoing and following embodiments, a number of pairs is 2 to 5. In one or more of the foregoing and following embodiments, at least one of a thickness of Si, a thickness of Mo or the number of pairs is different between the first adjust layer and the second adjust layer. In one or more of the foregoing and following embodiments, a thickness of the Mo layer is smaller than a thickness of the Si layer. In one or more of the foregoing and following embodiments, the thickness of the Si layer is in a range from 2 nm to 6 nm and the thickness of the Mo layer is in a range from 1.5 nm to 4.5 nm. In one or more of the foregoing and following embodiments, materials of the first and second absorber layers are different from each other. In one or more of the foregoing and following embodiments, the first absorber layer includes TaN. In one or more of the foregoing and following embodiments, the second absorber layer includes one or more of Pt, Ir, Re, Ru or an alloy thereof.

In accordance with another aspect of the present disclosure, a reflective mask includes a substrate, a reflective multilayer disposed on the substrate, a capping layer disposed on the reflective multilayer, a first absorber layer disposed on the capping layer, a multilayer disposed over the first absorber layer, and a second absorber layer, which is an uppermost layer of the reflective mask, disposed on the multilayer layer. In one or more of the foregoing and following embodiments, the multilayer includes one or more pairs of a Si layer and a Mo layer. In one or more of the foregoing and following embodiments, a number of pairs is 2 to 5. In one or more of the foregoing and following embodiments, a thickness of the Mo layer is smaller than a thickness of the Si layer. In one or more of the foregoing and following embodiments, the thickness of the Si layer is in a range from 2 nm to 6 nm and the thickness of the Mo layer is in a range from 1.5 nm to 4.5 nm. In one or more of the foregoing and following embodiments, materials of the first and second absorber layers are different from each other. In one or more of the foregoing and following embodiments, the first absorber layer includes TaN. In one or more of the foregoing and following embodiments, the second absorber layer includes one or more of Pt, Ir, Re, Ru or an alloy thereof.

In accordance with another aspect of the present disclosure, a reflective mask includes a circuit area, and a black border region surrounding the circuit area. Each of the circuit area and the black border region includes a substrate, a reflective multilayer disposed on the substrate, a capping layer disposed on the reflective multilayer, and a first absorber layer disposed on the capping layer. The black border region further includes a first multilayer disposed over the first absorber layer, and a second absorber layer disposed on the first multilayer layer. In one or more of the foregoing and following embodiments, the black border region further includes a second multilayer including one or more pairs of a Si layer and a Mo layer disposed over the second absorber layer. In one or more of the foregoing and following embodiments, the first multilayer includes one or more pairs of a Si layer and a Mo layer. In one or more of the foregoing and following embodiments, a number of pairs is 2 to 5. In one or more of the foregoing and following embodiments, at least one of a thickness of Si, a thickness of Mo or the number of pairs is different between the first adjust layer and the second adjust layer. In one or more of the foregoing and following embodiments, a thickness of the Mo layer is smaller than a thickness of the Si layer. In one or more of the foregoing and following embodiments, the thickness of the Si layer is in a range from 2 nm to 6 nm and the thickness of the Mo layer is in a range from 1.5 nm to 4.5 nm. In one or more of the foregoing and following embodiments, materials of the first and second absorber layers are different from each other. In one or more of the foregoing and following embodiments, the first absorption layer includes TaN. In one or more of the foregoing and following embodiments, the second absorption layer includes one or more of Pt, Ir, Re, Ru or an alloy thereof.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of manufacturing a reflective mask, the method comprising:
forming a photoresist layer over a mask blank, the mask blank including a substrate, a reflective multilayer on the substrate, a capping layer on the reflective multilayer, a first absorption layer on the capping layer, a first adjust layer on the first absorption layer, a second absorption layer on the first adjust layer, a second adjust layer on the second absorption layer, a third absorption layer on the second adjust layer, a fourth absorption layer on the third absorption layer and a hard mask layer on the fourth absorption layer;
patterning the photoresist layer;
patterning the hard mask layer by using the patterned photoresist layer as an etching mask;
performing a first absorber patterning of patterning the fourth absorption layer, the third absorption layer and the second adjust layer by using the patterned hard mask layer as an etching mask;
performing a second absorber patterning of patterning the first adjust layer, the second absorption layer and the first absorption layer by using the patterned fourth and third absorption layers as an etching mask; and
removing the patterned fourth and third absorption layers.

2. The method of claim 1, wherein at least one of the first and second adjust layers includes one or more pairs of a Si layer and a Mo layer.

3. The method of claim 2, wherein a number of pairs is 2 to 5.

4. The method of claim 3, wherein at least one of a thickness of Si, a thickness of Mo or the number of pairs is different between the first adjust layer and the second adjust layer.

5. The method of claim 1, wherein materials of the first, second, third and fourth absorption layers are different from each other.

6. The method of claim 5, wherein the first absorption layer includes TaN.

7. The method of claim 5, wherein the second absorption layer includes one or more of Pt, Ir, Re, Ru or an alloy thereof.

8. The method of claim 5, wherein the third absorption layer includes at least one of TaO or TaBO.

9. The method of claim 5, wherein the fourth absorption layer includes a silicide.

10. The method of claim 1, wherein the second absorber patterning comprises:
patterning the second absorption layer and the first adjust layer;
after the first adjust layer is patterned, removing the patterned hard mask layer; and
patterning the first absorption layer.

11. The method of claim 10, wherein the second absorber patterning further comprises forming a Si containing layer on side faces of the patterned second absorption layer before the first absorption layer is patterned.

12. The method of claim 1, further comprising:
forming absorber patterns composed of the first absorption layer by removing a part of the second adjust layer, the second absorption layer and the first adjust layer,
wherein a black border region includes the first absorption layer, the first adjust layer, the second absorption layer and the second adjust layer.

13. The method of claim 1, further comprising removing the patterned second adjust layer.

14. A method of manufacturing a reflective mask, the method comprising:
forming a photoresist layer over a mask blank, the mask blank including a substrate, a reflective multilayer on the substrate, a capping layer on the reflective multilayer, a first absorption layer on the capping layer, an adjust layer on the first absorption layer, a second absorption layer on the adjust layer and a hard mask layer on the second absorption layer;
patterning the photoresist layer;
patterning the hard mask layer by using the patterned photoresist layer as an etching mask;
performing a first absorber patterning of patterning the second absorption layer by using the patterned hard mask layer as an etching mask; and
performing a second absorber patterning of patterning the adjust layer and the first absorption layer by using the patterned second absorption layer as an etching mask;
forming absorber patterns composed of the first absorption layer by removing a part of the second absorption layer and the adjust layer,
wherein a black border region includes the first absorption layer, the adjust layer and the second absorption layer.

15. The method of claim 14, wherein the adjust layer includes 2 to 5 pairs of a Si layer and a Mo layer.

16. The method of claim 15, wherein a thickness of the Si layer is in a range from 2 nm to 6 nm and a thickness of the Mo layer is smaller than the thickness of the Si layer and is in a range from 1.5 nm to 4.5 nm.

17. The method of claim 15, wherein materials of the first and second absorption layers are different from each other.

18. The method of claim 15, wherein the second absorption layer include a silicide, and the first absorption layer includes Pt.

19. A reflective mask, comprising:
a substrate;
a reflective multilayer disposed on the substrate;
a capping layer disposed on the reflective multilayer;
a first absorber layer disposed on the capping layer;
a first multilayer disposed over the first absorber layer;
a second absorber layer disposed on the first multilayer; and
a second multilayer, which is an uppermost layer of the reflective mask, disposed over the second absorber layer.

20. The reflective mask of claim 19, wherein at least one of the first and second multilayers includes one or more pairs of a Si layer and a Mo layer.
